(19) United States
(12) Patent Application Publication
(10) Pub. No.: US 2007/0072367 A1
(43) Pub. Date: Mar. 29, 2007

(54) Method of manufacturing semiconductor silicon substrate

(75) Inventor: Hiroyuki Ode, Tokyo (JP)

Correspondence Address: MCDERMOTT WILL & EMERY LLP, 600 13TH STREET, N.W., WASHINGTON, DC, 20005-3096, US

(73) Assignee: ELPIDA MEMORY INC.

(21) Appl. No.: 11/526,756

(22) Filed: Sep. 26, 2006

(30) Foreign Application Priority Data
Sep. 28, 2005 (JP) 2005-281244

(51) Int. Cl. H01L 21/8242; H01L 21/20

(52) U.S. Cl. 438/243; 438/386

(57) ABSTRACT

The present invention provides a method of manufacturing a semiconductor silicon substrate provided with a capacitor structure having a capacitor hole, the capacitor hole having a depth of equal to or greater than 3 μm and an aspect ratio equal to or greater than 30, the method including at least: cleaning the capacitor hole provided on the substrate to be treated in the presence of carbon dioxide in a supercritical state under conditions of a temperature ranging from 31 to 100° C. and a pressure ranging from 18 to 40 MPa; and forming a metal thin film for capacitor electrodes on the capacitor hole provided on the substrate to be treated in the presence of carbon dioxide in a supercritical state under conditions of a temperature ranging from 100 to 350° C. and a pressure ranging from 7.2 to 12 MPa.

### BACKGROUND OF THE INVENTION

1. Field of the Invention

The present invention relates to a method of manufacturing a semiconductor silicon substrate, and more specifically, to a method of manufacturing a semiconductor silicon substrate in which a capacitor structure forming process is performed in the presence of carbon dioxide in a supercritical state.

2. Related Art

Since carbon dioxide in a supercritical state has both liquid and gas properties, utilization of the carbon dioxide in the supercritical state has been proposed in recent years in a semiconductor-related field.

Specifically, a method is proposed for forming both a copper diffusion prevention film and a copper film on a substrate to be treated while supplying the carbon dioxide in the supercritical state to the substrate to be treated (Japanese Patent Application Publication No. 2004-228526).

According to this method, formation of the copper diffusion prevention film and embedding of the copper film are made possible even for extremely fine patterns.

### BRIEF SUMMARY OF THE INVENTION

However, the reliability of wiring obtained by the method disclosed in the patent application publication becomes sometimes lower, for example, the resistance value of the wiring becomes larger than expected, or disconnection occurs, in particular when the wiring pattern has a higher aspect ratio and a finer pattern.

An object of the present invention is to provide a method of manufacturing a semiconductor silicon substrate having a capacitor structure with high reliability even among the methods of manufacturing the semiconductor substrate by using carbon dioxide in a supercritical state.

The present inventors have found out that, when manufacturing a semiconductor silicon substrate with a capacitor structure having a capacitor hole with a depth equal to or greater than 3 μm or more, and an aspect ratio of the capacitor hole equal to or greater than 30, mere use of carbon dioxide in a supercritical state is not enough to make the semiconductor silicon substrate a highly-reliable one.

As a result of extensive investigations, the inventors have completed the present invention by finding out that the object of the present invention can be attained by a method of manufacturing a semiconductor silicon substrate comprising at least

a cleaning process for cleaning the substrate to be treated in the presence of carbon dioxide in a supercritical state under a specific range of a temperature of 31 to 100° C. and a pressure of 18 to 40 MPa, and

a metal thin film forming process for capacitor electrodes for forming a metal thin film on a capacitor hole provided on the substrate to be treated in the presence of carbon dioxide in a supercritical state under a specific range of a temperature of 100 to 350° C. and a pressure of 7.2 to 12 MPa.

More specifically, the present invention provides:

[1] a method of manufacturing a semiconductor silicon substrate provided with a capacitor structure having a depth of a capacitor hole equal to or greater than 3 μm, and an aspect ratio of the capacitor hole equal to or greater than 30, the method of manufacturing the semiconductor silicon substrate being characterized by comprising at least:

cleaning the capacitor hole provided on a substrate to be treated in the presence of carbon dioxide in a supercritical state under conditions of a temperature ranging from 31 to 100° C. and a pressure ranging from 18 to 40 MPa; and

forming a metal thin film for capacitor electrodes on the capacitor hole provided on the substrate to be treated in the presence of carbon dioxide in a supercritical state under conditions of a temperature ranging from 100 to 350° C. and a pressure ranging from 7.2 to 12 MPa.

Moreover, the present invention provides:

[2] the method of manufacturing the semiconductor silicon substrate described in item [1], characterized in that the metal thin film includes at least any one of films selected from a group of a metal thin film consisting of a single element, a conductive nitride film, and a conductive oxide film.

Moreover, the present invention provides:

[3] the method of manufacturing the semiconductor silicon substrate described in item [1] or [2], characterized in that the metal thin film has a thickness equal to or less than 20 nm.

Moreover, the present invention provides:

[4] the method of manufacturing the semiconductor silicon substrate described in any one of items [1] to [3], characterized in that the above each process is performed while the substrate to be treated is held inside the same vessel.

Moreover, the present invention provides:

[5] a semiconductor device, characterized by including the semiconductor substrate obtained by the method of manufacturing the semiconductor substrate described in any one of items [1] to [4].

The present invention provides a method of manufacturing a semiconductor silicon substrate having a capacitor structure with high reliability even among the methods of manufacturing the semiconductor substrate by using carbon dioxide in a supercritical state.

### BRIEF DESCRIPTION OF THE DRAWINGS

The above and other objects and features of the invention will appear more fully hereinafter from a consideration of the following description taken in connection with the accompanying drawing wherein one example is illustrated by way of example, in which;

FIG. 1 is a schematic cross-sectional diagram of an essential part illustrating a state where a capacitor hole is formed on a substrate to be treated;

FIG. 2 is a schematic cross-sectional diagram of the essential part illustrating a state where a metal thin film is formed on the surface of the capacitor hole;

FIG. 3 is a schematic diagram showing one embodiment of construction of a manufacturing device for carrying out a manufacturing method according to the present invention; and

FIG. 4 is a diagram showing a process flow for describing one embodiment of a manufacturing method according to the present invention.

### DETAILED DESCRIPTION OF THE INVENTION

A manufacturing method according to the present invention comprises at least a cleaning process for cleaning a capacitor hole provided on a substrate to be treated, and a metal thin film forming process for capacitor electrodes for forming a metal thin film on the capacitor hole provided on the substrate to be treated. First, the substrate to be treated used for the present invention is described.

The substrate to be treated may be exemplified by a semiconductor silicon wafer before being subjected to the cleaning process and the metal thin film forming process for capacitor electrodes.

Such a semiconductor silicon wafer may be exemplified by a product subjected to one or more processes represented by front end processes such as an epitaxial layer forming process, an isolation forming process, a well forming process, a gate insulation film forming process, a gate electrode forming process, a spacer forming process, and a source/drain forming process.

The substrate to be treated used for the present invention is a product having a capacitor hole.

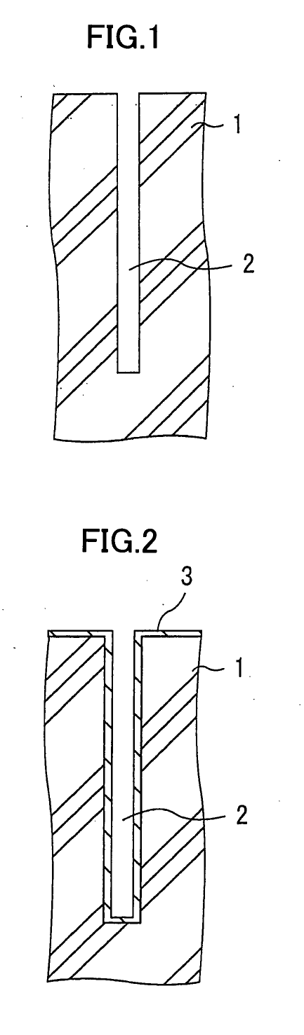

Now, FIG. 1 is a schematic cross-sectional diagram of an essential part illustrating a state where a capacitor hole 2 is formed on a substrate to be treated 1.

The capacitor hole 2 has a depth equal to or greater than 3 μm, and an aspect ratio of the capacitor hole 2 equal to or greater than 30.

The capacitor hole 2 preferably has a depth equal to or greater than 3 μm, more preferably equal to or greater than 3.5 μm, and still more preferably equal to or greater than 4 μm.

In addition, the capacitor hole 2 further preferably has a depth equal to or less than 5 μm.

The method of manufacturing the semiconductor substrate according to the present invention is specially adapted for the metal thin film forming process for capacitor electrodes including a fine structure having such a high aspect ratio.

The capacitor hole preferably has an aspect ratio equal to or greater than 30, more preferably equal to or greater than 35, and still more preferably equal to or greater than 40.

In addition, the capacitor hole further preferably has an aspect ratio equal to or less than 50.

Next, the cleaning process in the present invention is described.

The cleaning process in the present invention applies cleaning to the capacitor hole provided on the substrate to be treated.

It is necessary to conduct the cleaning process in the presence of carbon dioxide in a supercritical state.

Here, the carbon dioxide in the supercritical state means carbon dioxide under conditions of temperature and/or pressure beyond the critical point of carbon dioxide of a temperature of 31° C. and a pressure of 7.38 MPa. In these conditions, the carbon dioxide exhibits properties of both liquid and gas.

The cleaning process in the present invention is carried out under conditions of a temperature ranging from 31 to 100° C. and a pressure ranging from 18 to 40 MPa among the supercritical states.

When the temperature is lower than 31° C., the carbon dioxide cannot maintain the supercritical state, and cleaning efficiency is significantly decreased due to deceleration of diffusion of a cleaning reagent inside the capacitor hole and diffusion of a detached contaminant to the outside of the capacitor hole.

Moreover, when the temperature exceeds 100° C., carbon dioxide in a supercritical state comes to have low density as in a gaseous state, and therefore sufficiently high solubility of a contaminant cannot be obtained.

The temperature preferably ranges from 35 to 90° C., and more preferably ranges from 40 to 80° C.

Furthermore, when the pressure is lower than 18 MPa, similarly, sufficiently high solubility of the contaminant cannot be obtained, and thus efficiency in cleaning the wafer is decreased.

Moreover, when the pressure exceeds 40 MPa, it is difficult to assure the safety of the use of reactors, pumps, high-pressure valves and the like which constitute a manufacturing device used in the present invention. Moreover, when the pressure is equal to or greater than 40 MPa, an increase in density relative to pressure becomes negligibly small, and an increase in solubility in a region of a pressure equal to or greater than the above value is small. Accordingly, the use of pressure of carbon dioxide exceeding 40 MPa cannot be deemed efficient from the viewpoint described above.

The pressure preferably ranges from 18 to 35 MPa, and more preferably ranges from 20 to 30 MPa.

A cleaning reagent can be used for the cleaning process in the present invention.

The cleaning reagent may be specifically exemplified by hexafluoroacetylacetonate, acetylacetone, ethylacetoacetate, dimethylmaleate, 1,1,1-trifluoropentane-2,4-dione,

2,6-dimethylpentanedione-3,5-dione,

2,2,7-trimethyloctane-2,4-dione,

2,2,6,6-tetramethylheptane-3,5-dione, a chelating agent such as ethylenediaminetetraacetic acid,

an organic acid such as formic acid, acetic acid, oxalic acid, maleic acid, and nitrilotriacetic acid,

an inorganic acid such as hydrogen chloride, hydrogen fluoride, and phosphoric acid,

a nitrogen-containing compound such as ammonia and ethanolamine,

alcohols such as ethanol, and

a surface active agent such as perfluoropolyether (PFPE).

The cleaning reagent can be used alone or in combination of two or more kinds.

Next, the metal thin film forming process for capacitor electrodes in the present invention is described.

FIG. 2 is a schematic cross-sectional diagram of an essential part illustrating a state where the metal thin film 3 is formed on the surface of the capacitor hole 2.

The metal thin film forming process for capacitor electrodes in the present invention is specifically, for example, for forming the metal thin film 3 onto the capacitor hole 2 provided on the substrate 1 to be treated.

It is necessary to conduct the metal thin film forming process for capacitor electrodes in the presence of carbon dioxide in a supercritical state.

The metal thin film forming process for capacitor electrodes in the present invention is carried out under conditions of a temperature ranging from 100 to 350° C., and a pressure ranging from 7.2 to 12 MPa among the above supercritical states.

When the temperature is lower than 100° C., a sufficient amount of heat of reaction for forming the metal thin film cannot be obtained, and hence film forming speed is significantly decreased. When the temperature exceeds 350° C., a reverse reaction (for example, a reaction in which a formed film returns to a precursor) cannot be neglected, or the solubility of the precursor in the carbon dioxide in the supercritical state is decreased, and thus film forming speed is decreased.

The temperature preferably ranges from 120 to 300° C., and more preferably ranges from 150 to 250° C.

Furthermore, when the pressure is lower than 7.2 MPa, the density of the carbon dioxide is not sufficiently high, and hence a film forming precursor becomes difficult to dissolve. When the pressure exceeds 12 MPa, the viscosity of the carbon dioxide is increased, and the precursor becomes difficult to enter the capacitor hole, resulting in decrease of film forming efficiency on the bottom of the capacitor hole.

The pressure is preferably ranging from 7.5 to 12 MPa, and more preferably ranging from 8 to 11 MPa.

The metal thin film may be exemplified by a metal thin film consisting of a single element such as iridium, platinum, and ruthenium, a conductive nitride film consisting of titanium nitride and tantalum nitride, and a conductive oxide film consisting of iridium oxide and ruthenium oxide.

The metal thin film can be used alone or in combination of two or more kinds.

The metal thin film forming process for capacitor electrodes can be carried out by a method of causing a metal thin film precursor reagent to act on the capacitor hole provided on the substrate to be treated, a method of previously dissolving a film forming precursor in the carbon dioxide in the supercritical state, and causing such a dissolved material to act on the capacitor hole provided on the substrate to be treated, a method of reacting the film forming precursor dissolved in the carbon dioxide in the supercritical state with a reaction reagent (oxygen, ozone, hydrogen, nitrogen, ammonia, water, or the like) on the substrate to be treated, or the like.

When the metal thin film is formed on the surface of the capacitor hole, for example, the metal thin film can be formed by a method of causing the metal thin film precursor reagent to act on the capacitor hole provided on the substrate to be treated in the presence of the carbon dioxide in the supercritical state, or the like.

The process of forming the metal thin film is preferably carried out under conditions of a temperature ranging from 150 to 250° C. and a pressure ranging from 8 to 11 MPa.

The metal thin film precursor reagent may be specifically exemplified by

bis(ethylcyclopentadienyl)ruthenium,

tris(2,4-octadionato)ruthenium,

pentakis(dimethylamino)tantalum, pentaethoxytantalum,

tetra-t-butoxytitanium,

tetrakis(N-ethyl-N-methylamino)titanium,

iridium acetylacetone, and platinum acetylacetone.

For example, when the iridium acetylacetone is used as the metal thin film precursor reagent, and allowed to react with hydrogen on the substrate to be treated, iridium deposits on the substrate to be treated.

Thus, an iridium film can be formed on the surface of the capacitor hole.

For example, when the platinum acetylacetone is used as the metal thin film precursor reagent, and allowed to react with hydrogen on the substrate to be treated, platinum deposits on the substrate to be treated.

Thus, a platinum film can be formed on the surface of the capacitor hole.

For example, when the bis(ethylcyclopentadienyl)ruthenium and/or the tris(2,4-octadionato)ruthenium are used as the metal thin film precursor reagent, and allowed to react with hydrogen on the substrate to be treated, ruthenium deposits on the surface of the substrate to be treated.

Thus, a ruthenium film can be formed on the surface of the capacitor hole.

For example, when the pentakis(dimethylamino)tantalum is used as the barrier film precursor reagent, and allowed to react with ammonia on the substrate to be treated, tantalum nitride deposits on the substrate to be treated.

When the pentaethoxytantalum and the ammonia are used, the same result is obtained.

Thus, a tantalum nitride film can be formed on the surface of the capacitor hole.

For example, when the tetra-t-butoxytitanium is used as the electrode film precursor reagent, and allowed to react with ammonia on the substrate to be treated, titanium nitride deposits on the substrate to be treated.

When the tetrakis(N-ethyl-N-methylamino)titanium and the ammonia are used, the same result is obtained.

Thus, a titanium nitride film can be formed on the surface of the capacitor hole.

For example, when the iridium acetylacetone is used as the metal thin film precursor reagent, and allowed to react with oxygen on the substrate to be treated, iridium oxide deposits on the substrate to be treated.

Thus, an iridium oxide film can be formed on the surface of the capacitor hole.

For example, when the bis(ethylcyclopentadienyl)ruthenium and/or the tris(2,4-octadionato)ruthenium are used as the metal thin film precursor reagent, and allowed to react with oxygen on the substrate to be treated, ruthenium oxide deposits on the substrate to be treated.

Thus, a ruthenium oxide film can be formed on the surface of the capacitor hole.

The metal thin film precursor reagent can be used alone or in combination of two or more kinds.

The metal thin film can be formed on the surface of the capacitor hole by using the metal thin film forming process for capacitor electrodes, and the thickness of this metal thin film is preferably equal to or less than 20 nm.

The thickness of the metal thin film is more preferably equal to or less than 15 nm, and still more preferably equal to or less than 10 nm.

Moreover, the thickness of the metal thin film is further preferably equal to or greater than 5 nm.

After completion of the metal thin film forming process for capacitor electrodes, the cleaning process can be further applied to the capacitor hole on which the metal thin film is formed, if necessary.

In the manufacturing method according to the present invention, the processes described above can be continuously carried out in a single manufacturing device.

A semiconductor silicon substrate can be obtained through the processes described above.

Then, a semiconductor device such as DRAM can be obtained by using the semiconductor silicon substrate.

Next, the manufacturing method according to the present invention and the manufacturing device are further described in detail based on examples.

The present invention is not limited in any way by these examples.

### EXAMPLE 1

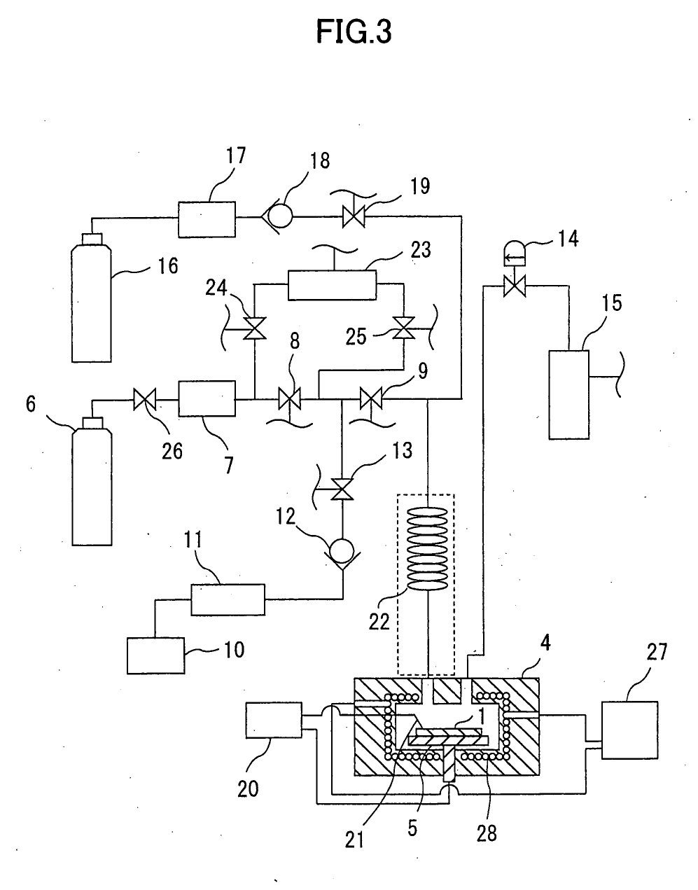

FIG. 3 is a schematic diagram showing one embodiment of construction of a manufacturing device for carrying out a manufacturing method according to the present invention.

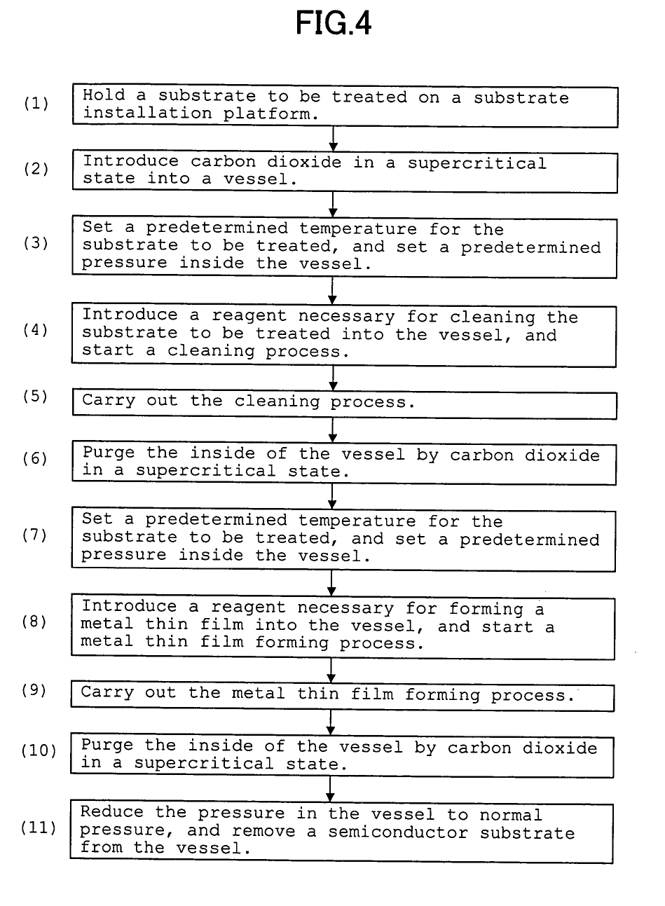

Moreover, FIG. 4 is a diagram showing a process flow for describing a manufacturing method according to the present invention.

The manufacturing method according to the present invention is described with reference to FIGS. 3 and 4.

First, the substrate to be treated 1 is held on the substrate installation platform 5 inside the vessel 4.

This substrate to be treated 1 was obtained by using a semiconductor silicon wafer through each process including the epitaxial layer forming process, the isolation forming process, the well forming process, the gate insulation film forming process, the gate electrode forming process, the spacer forming process, and the source/drain forming process among the processes described above.

As shown in FIG. 1, the capacitor hole 2 is provided on the substrate to be treated.

The depth of this capacitor hole 2 was equal to or greater than 3 μm, and the aspect ratio was equal to or greater than 30.

When the cleaning process in the manufacturing method of the present invention is carried out, as shown in FIG. 3, a temperature in the vessel 4 is required to be increased to the range of 31 to 100° C., and a pressure in the vessel 4 is required to be adjusted ranging from equal to or greater than 18 MPa by introducing carbon dioxide into the vessel 4 through a carbon dioxide cylinder 6, a high-pressure pump 7 for supplying the carbon dioxide, and high-pressure valves 26, 8 and 9.

First, the temperature of the substrate to be treated was measured by using a thermocouple 21, and set to 50° C. by using a temperature controller 20. When the temperature is excessively increased, cooling water circulates inside a cooling tube 28 connected to a cooling water circulator 27, and thus a temperature increase can be suppressed. Next, a pressure inside the vessel 4 was set to 20 Mpa, and a cleaning reagent was introduced into the vessel 4 from a reagent vessel 10 through a pump for adding a reagent 11, a check valve for adding the reagent 12, and high-pressure valves 13 and 9, and thus the cleaning process for eliminating residues, organic contaminants deposited on the surface of the capacitor hole, and the like after etching was carried out.

Such residues and the organic contaminants may be exemplified by residual solids or residual liquid materials after processes including an etching process such as reactive ion etching, wet etching, dry etching and plasma etching, chemical mechanical polishing (CMP), and the like.

In the present example, ethanol is used as the cleaning reagent, but the use of such a cleaning reagent can be omitted in the cleaning process.

After completion of the cleaning process, the introduction of the cleaning reagent into the vessel 4 was discontinued, and while carbon dioxide was introduced into the vessel 4 through the carbon dioxide cylinder 6, the high-pressure pump for supplying carbon dioxide 7, and the high-pressure valves 26, 8 and 9, the cleaning reagent and the like inside the vessel 4 were collected from a back pressure regulator 14 through a reagent recovery chamber 15, and then a purging process for discharging excessive carbon dioxide to the outside of the system was carried out.

This process replaced the atmosphere in the vessel 4 by pure carbon dioxide.

The temperature of the substrate to be treated 1 was set to 200° C., and the pressure inside the vessel 4 was set to 10 Mpa. Then bis(ethylcyclopentadienyl)ruthenium was introduced into the vessel 4 from the reagent vessel 10 through the pump for adding the reagent 11, the check valve for adding the reagent 12, and the valves 13 and 9. Moreover, hydrogen was introduced from a hydrogen cylinder 16 through a flow controller 17, a check valve 18, and a high-pressure valve 19. Various kinds of reagents to be used were introduced into the vessel 4 through a mixing loop 22 provided to efficiently mix the reagents with carbon dioxide. In addition, a heating means for converting carbon dioxide inside the mixing loop into a supercritical state is provided in this mixing loop 22 (dotted line part in FIG. 3).

In the present example, the mixing loop was used. However, according to embodiments of the present invention, a mixing tank can be separately provided instead of the mixing loop or together with the mixing loop (not shown). An agitation means such as a mechanical stirrer can be provided in the mixing tank.

A ruthenium film was formed on the surface of the capacitor hole by the above-mentioned operation.

When a reagent to be used is a solid, the reagent is dissolved in carbon dioxide in a supercritical state introduced from a high-pressure valve 24 in a chamber for dissolving a solid reagent 23, and then the dissolved material is introduced into the vessel 4 through high-pressure valves 25 and 9. Thus the metal thin film 3 can be formed on the surface of the capacitor hole 2.

After completion of the metal thin film forming process for capacitor electrodes for forming the ruthenium film, the introduction of the bis(ethylcyclopentadienyl)ruthenium and the hydrogen into the vessel 4 was discontinued, and while carbon dioxide was introduced into the vessel 4 as with the previous case, a purging process for discharging the film forming precursor and reaction by-products in the vessel 4 from the back pressure regulator 14 to the outside of the system was carried out.

This process replaced the atmosphere in the vessel 4 by pure carbon dioxide.

Subsequently, exactly the same process as the previous cleaning process was carried out.

Then, the heating of the substrate installation platform 5 was discontinued, the vessel 4 was cooled, and the pressure in the vessel 4 was returned to normal pressure to obtain a semiconductor silicon substrate.

The metal thin film forming process for capacitor electrodes for forming the metal thin film on the capacitor hole was described in the present example. However, for example, in addition to a lower electrode obtained in this process, a metal thin film can be formed on an upper electrode after a capacitance insulation film is formed on the lower electrode under exactly the same conditions as in the metal thin film forming process for capacitor electrodes described in the present example.

As described above, the semiconductor silicon substrate can be obtained by the method for continuously treating the substrate to be treated through the cleaning process, the metal thin film forming process for capacitor electrodes, and the cleaning process.

A semiconductor device such as DRAM obtained by using the semiconductor silicon substrate was operated normally, and exhibited excellent reliability.

The present invention is not limited to the above described embodiments, and various variations and modifications may be possible without departing from the scope of the present invention.

This application is based on the Japanese Patent application No. 2005-281244 filed on Sep. 28, 2005, entire content of which is expressly incorporated by reference herein.

What is claimed is:

1. A method of manufacturing a semiconductor silicon substrate provided with a capacitor structure having a capacitor hole, the capacitor hole having a depth of equal to or greater than 3 μm and an aspect ratio to or greater than 30, the method comprising at least:
cleaning the capacitor hole provided on a substrate to be treated in the presence of carbon dioxide in a supercritical state under conditions of a temperature ranging from 31 to 100° C. and a pressure ranging from 18 to 40 MPa; and
forming a metal thin film for capacitor electrodes on the capacitor hole provided on the substrate to be treated in the presence of carbon dioxide in a supercritical state under conditions of a temperature ranging from 100 to 350° C. and a pressure ranging from 7.2 to 12 MPa.

2. The method of claim 1, wherein the metal thin film includes at least one selected from a group of a metal thin film consisting of a single element, a conductive nitride film, and a conductive oxide film.

3. The method of claim 2, wherein the metal thin film has a thickness equal to or less than 20 nm.

4. The method of claim 1, wherein cleaning of the capacitor hole and forming of the metal thin film are performed while the substrate to be treated is held inside one vessel.

5. The method of claims 2, wherein cleaning of the capacitor hole and forming of the metal thin film are performed while the substrate to be treated is held inside one vessel.

6. The method of claim 3, wherein cleaning of the capacitor hole and forming of the metal thin film are performed while the substrate to be treated is held inside one vessel.

7. A semiconductor device, including the semiconductor substrate obtained by the method of claim 1.

8. A semiconductor device, including the semiconductor substrate obtained by the method of claim 2.

9. A semiconductor device, including the semiconductor substrate obtained by the method of claim 3.

10. A semiconductor device, including the semiconductor substrate obtained by the method of claim 4.

11. A semiconductor device, including the semiconductor substrate obtained by the method of claim 5.

12. A semiconductor device, including the semiconductor substrate obtained by the method of claim 6.
